(19) United States
(12) Patent Application Publication
(10) Pub. No.: US 2025/0169061 A1
(43) Pub. Date: May 22, 2025

(54) SEMICONDUCTOR DEVICE

(71) Applicant: Samsung Electronics Co., Ltd., Suwon-si (KR)

(72) Inventors: Sungjoon Park, Suwon-si (KR); Terai Masayuki, Suwon-si (KR)

(21) Appl. No.: 18/933,076

(22) Filed: Oct. 31, 2024

(30) Foreign Application Priority Data
Nov. 20, 2023 (KR) 10-2023-0161028

(51) Int. Cl. H10B 12/00

(52) U.S. Cl. CPC H10B 12/315; H10B 12/05

(57) ABSTRACT

A semiconductor device includes a substrate, a bit line extending on the substrate in a first horizontal direction, a first mold layer on the bit line, wherein the first mold layer includes a mold opening portion exposing a portion of an upper surface of the bit line and extends in a second horizontal direction, a channel layer arranged on the bit line, a word line arranged within the mold opening portion and extending in the second horizontal direction, a gate insulating layer arranged between the word line and the channel layer, a capacitor structure on the first mold layer, a contact layer between the channel layer and the capacitor structure, and an auxiliary insulating pattern arranged to overlap the contact layer and the gate insulating layer in the first horizontal direction and extending on the word line in the second horizontal direction.

### CROSS-REFERENCE TO RELATED APPLICATION

This application is based on and claims priority under 35 U.S.C. § 119 to Korean Patent Application No. 10-2023-0161028, filed on Nov. 20, 2023, in the Korean Intellectual Property Office, the disclosure of which is incorporated by reference herein in its entirety.

### BACKGROUND

The inventive concept relates to a semiconductor device and a method of manufacturing the semiconductor device, and more particularly, to a semiconductor device including a channel structure and a method of manufacturing the semiconductor device.

Due to the development of electronic technology, down-scaling of semiconductor devices is occurring rapidly, and accordingly, a transistor having a channel layer using an oxide semiconductor material has been proposed to reduce leakage current through a channel area.

Due to damage to agate insulating layer in a process of forming a vertical channel transistor (VCT) structure, time dependent dielectric breakdown (TDDB) reliability between a contact layer, a gate insulating layer, and a word line is weakened.

### SUMMARY

An aspect of the inventive concept provides a semiconductor device including an auxiliary insulating pattern arranged to overlap a contact layer and a gate insulating layer in a horizontal direction.

According to an aspect of the inventive concept, there is provided a semiconductor device including a substrate, a bit line extending on the substrate in a first horizontal direction, a first mold layer on the bit line, wherein the first mold layer includes a mold opening portion exposing a portion of an upper surface of the bit line and extends in a second horizontal direction crossing the first horizontal direction, a channel layer arranged on the bit line, a word line arranged within the mold opening portion and extending in the second horizontal direction, a gate insulating layer arranged between the word line and the channel layer, a capacitor structure on the first mold layer, a contact layer between the channel layer and the capacitor structure, and an auxiliary insulating pattern arranged to overlap the contact layer and the gate insulating layer in the first horizontal direction and extending on the word line in the second horizontal direction.

According to another aspect of the inventive concept, there is provided a semiconductor device including a substrate, a bit line extending on the substrate in a first horizontal direction, a first mold layer on the bit line, wherein the first mold layer includes a mold opening portion exposing a portion of an upper surface of the bit line and extends in a second horizontal direction crossing the first horizontal direction, a channel layer arranged on the bit line, a word line arranged within the mold opening portion and extending in the second horizontal direction, a gate insulating layer arranged between the word line and the channel layer, a capacitor structure on the first mold layer, a contact layer between the channel layer and the capacitor structure, and an auxiliary insulating pattern arranged between the word line and the gate insulating layer to extend in the second horizontal direction and overlap the contact layer and the gate insulating layer in the first horizontal direction, wherein the word line includes a first word line arranged on a sidewall of the gate insulating layer, and a second word line arranged on the first word line and being long in a vertical direction than the first word line.

According to another aspect of the inventive concept, there is provided a semiconductor device including a substrate, a bit line extending on the substrate in a first horizontal direction, a first mold layer on the bit line, wherein the first mold layer includes a mold opening portion exposing a portion of an upper surface of the bit line and extends in a second horizontal direction crossing the first horizontal direction, a channel layer arranged on the bit line, a word line, which is arranged within the mold opening portion and extends in the second horizontal direction, wherein the word line includes a first word line arranged on the channel layer and a second word line arranged on the first word line and being long in a vertical direction than the first word line, a gate insulating layer arranged between the word line and the channel layer, a capacitor structure on the first mold layer, a contact layer between the channel layer and the capacitor structure, and an auxiliary insulating pattern between the word line and the gate insulating layer to extend in the second horizontal direction, wherein the auxiliary insulating pattern is arranged to overlap the contact layer and the gate insulating layer in the first horizontal direction and contact an upper surface of the first word line and a portion of a sidewall of the second word line.

### BRIEF DESCRIPTION OF THE DRAWINGS

Embodiments of the inventive concept will be more clearly understood from the following detailed description taken in conjunction with the accompanying drawings in which:

FIG. 1 is a layout diagram illustrating a semiconductor device according to embodiments;

FIG. 2 is an enlarged layout diagram of a portion of a cell array area of FIG. 1;

FIG. 3 is a cross-sectional view of the semiconductor device of FIG. 2, taken along a line A1-A1′;

FIG. 4 is an enlarged view of a portion CX1 of FIG. 3; and

FIGS. 5 to 18 are cross-sectional views illustrating a method of manufacturing a semiconductor device, according to embodiments.

### DETAILED DESCRIPTION OF THE EMBODIMENTS

Hereinafter, the inventive concept will be described more fully with reference to the accompanying drawings, in which embodiments of the inventive concept are shown. Like reference numerals in the drawings denote like elements, and thus their description will be omitted.

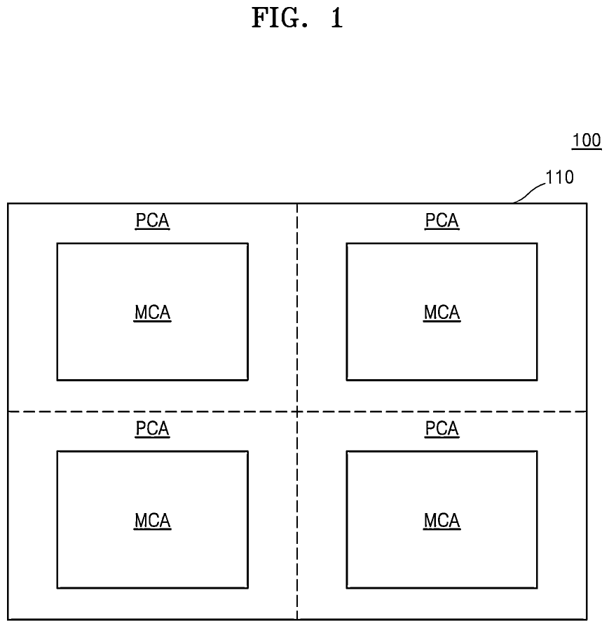

FIG. 1 is a layout diagram illustrating a semiconductor device 100 according to embodiments.

Referring to FIG. 1, the semiconductor device 100 may include a substrate 110 including a cell array area MCA and a peripheral circuit area PCA. In some embodiments, the cell array area MCA may be a memory cell area of a dynamic random access memory (DRAM) device, and the peripheral circuit area PCA may be a core area or a peripheral circuit area of the DRAM device. For example, the peripheral circuit area PCA may include peripheral circuit transistors (not shown) configured to transmit signals and/or power to memory cell arrays included in the cell array area MCA. In embodiments, the peripheral circuit transistors (not shown) may configure various circuits, such as a command decoder, a control logic, an address buffer, a row decoder, a column decoder, a sense amplifier, a data input/output circuit, or the like.

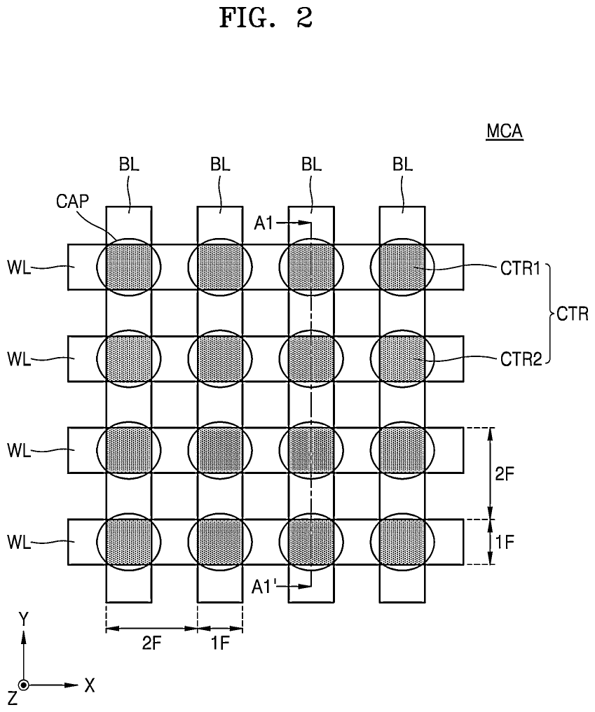

FIG. 2 is an enlarged layout diagram of the cell array area MCA of FIG. 1.

Referring to FIG. 2, a plurality of bit lines BL extending in a first horizontal direction (Y direction) and a plurality of word lines WL extending in a second horizontal direction (X direction) may be arranged in the cell array area MCA of the substrate 110. A plurality of cell transistors CTR may be arranged at intersections of the plurality of word lines WL and the plurality of bit lines BL. A plurality of cell capacitors CAP may be respectively arranged on the plurality of cell transistors CTR.

The plurality of word lines WL may be arranged to be spaced apart in the first horizontal direction (Y direction). The plurality of cell transistors CTR may include first cell transistors CTR1 and second cell transistors CTR2, which are alternately arranged in the first horizontal direction (Y direction). The first cell transistors CTR1 and the second cell transistors CTR2 may be respectively arranged on the plurality of word lines WL.

A first cell transistor CTR1 and a second cell transistor CTR2 adjacent each other may have a mirror symmetrical structure with respect to each other. For example, the first cell transistor CTR1 and the second cell transistor CTR2 may have a mirror symmetrical structure with respect to a center line between the first cell transistor CTR1 and the second cell transistor CTR2, wherein the center line extends in the second horizontal direction (X direction).

In embodiments, a width of each of the plurality of word lines WL may be 1F, a pitch (e.g., a sum of the width of a word line and a gap between two adjacent word lines) of the plurality of word lines WL may be 2F, a width of each of the plurality of bit lines BL may be 1F, a pitch (e.g., a sum of the width of a bit line BL and a gap between two adjacent word lines) of the plurality of bit lines BL may be 2F, and a unit area for forming one cell transistor CTR may be 4F². Accordingly, the cell transistor CTR may have a crosspoint type that requires a relatively small unit area, which may facilitate improving integration of the semiconductor device 100. For example, the crosspoint type cell transistor may be a transistor formed on a cross point between a bit line BL and a word line WL.

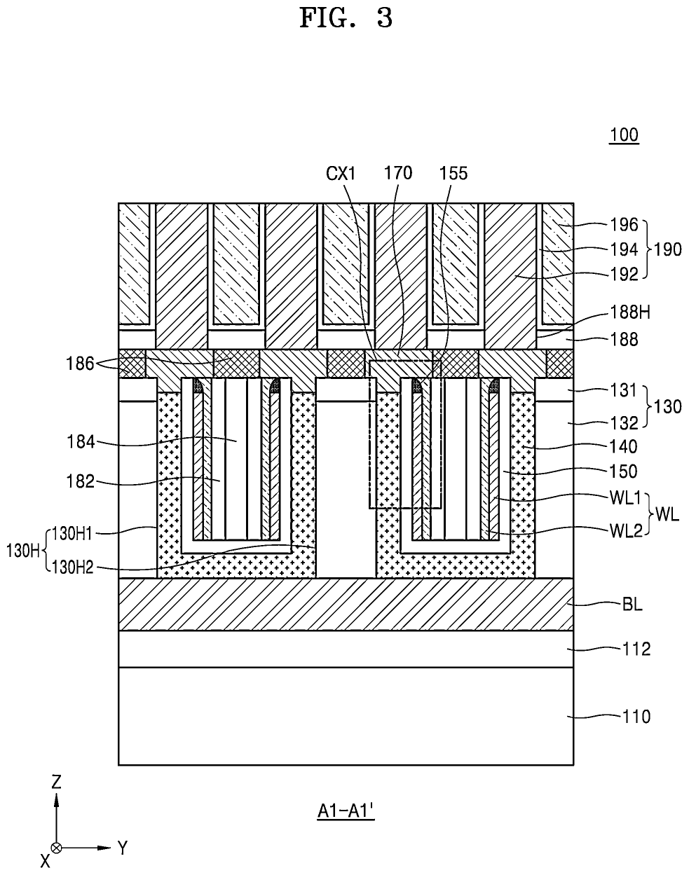

FIG. 3 is a cross-sectional view of the semiconductor device of FIG. 2, taken along a line A1-A1′.

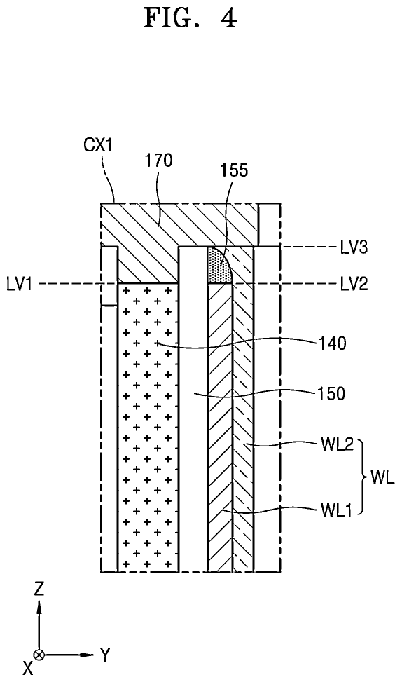

FIG. 4 is an enlarged view of a portion CX1 of FIG. 3.

As shown in FIG. 3, a lower insulating layer 112 may be arranged on the substrate 110. The substrate 110 may include silicon, for example, single crystalline silicon, polycrystalline silicon, or amorphous silicon. In some embodiments, the substrate 110 may include at least one selected from Ge, SiGe, SiC, GaAs, InAs, and InP. In some embodiments, the substrate 110 may include a conductive area, for example, a well doped with an impurity or a structure doped with an impurity. The lower insulating layer 112 may include or may be an oxide film, a nitride film, or a combination thereof.

A bit line BL extending (e.g., longitudinally extending) in the first horizontal direction (Y direction) may be arranged on the lower insulating layer 112. In embodiments, the bit line BL may include Ti, TiN, Ta, TaN, W, WN, TiSiN, WSiN, polysilicon, or a combination thereof. For example, the bit line BL may include or be formed of a conductive layer (not shown) and conductive barrier layers (not shown) respectively arranged on upper and lower surfaces of the conductive layer. A bit line insulating layer (not shown) extending in the first horizontal direction (Y direction) may be arranged on a sidewall (e.g., on opposite sidewalls) of the bit line BL. For example, the bit line insulating layer may fill a space between two adjacent bit lines BL and may be formed at the same height as the bit line BL.

A first mold layer 130 may be arranged on the bit line BL and the bit line insulating layer. The first mold layer 130 may include a plurality of mold opening portions 130H. The plurality of mold opening portions 130H may include a first sidewall 130H1 and a second sidewall 130H2, which are opposite to each other. The upper surface of the bit line BL may be exposed at a bottom portion of each of the plurality of mold opening portions 130H. The plurality of mold opening portions 130H may also be referred to as mold openings.

The first mold layer 130 may include at least one of silicon oxide, silicon nitride, and silicon oxynitride. According to an embodiment, the first mold layer 130 may be formed as a multi-layered structure. For example, the first mold layer 130 may include a first insulating film 131 and a second insulating film 132. At this time, the first insulating film 131 may include or be formed of silicon nitride, and the second insulating film 132 may include or be formed of silicon oxide. The thickness of the second insulating film 132 in a vertical direction (Z direction) may be greater than the thickness of the first insulating film 131 in the vertical direction, but the inventive concept is not limited thereto.

The second insulating film 132 may be arranged on the bit line BL. The first insulating film 131 may be arranged on the second insulating film 132. FIG. 3 illustrates that the first mold layer 130 is formed of or includes two insulating films, but the inventive concept is not limited thereto. For example, the first mold layer 130 may be formed as a single-layered structure or may include or be formed of three or more multiple layers.

A plurality of channel layers 140 may be arranged on inner walls of the plurality of mold opening portions 130H. Each of the plurality of channel layers 140 may include a first portion extending in the first horizontal direction (Y direction) from the bottom portion of the plurality of mold opening portions 130H and a second portion connected to and extending from the first portion, and arranged on the first sidewall 130H1 and the second sidewall 130H2 of the plurality of mold opening portions 130H. For example, each of the plurality of channel layers 140 may have a U-shaped vertical cross section.

The second portion of the plurality of channel layers 140 may include a first sidewall and a second sidewall, which are opposite to each other. The first sidewall may be in contact with a gate insulating layer 150, and the second sidewall may be in contact with the first mold layer 130. Each of the plurality of channel layers 140 may have an upper surface arranged at a lower level than that of an upper/top surface of the first mold layer 130. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact. The top/upper surface of the first mold layer 130 may be parallel or substantially parallel to a horizontal plane.

In embodiments, the plurality of channel layers 140 may each include an oxide semiconductor material. The plurality of channel layers 140 may each include an oxide semiconductor material including indium. For example, the oxide semiconductor material may include or be formed of at least one of InGaZnOx (IGZO), Sn-doped IGZO, W-doped IGZO, and InZnOx (IZO).

FIG. 3 illustrates that each of the plurality of channel layers 140 is formed of or includes a single layer, but the inventive concept is not limited thereto. For example, each of the plurality of channel layers 140 may be formed in a stacked structure including a first oxide semiconductor layer and a second oxide semiconductor layer. At this time, each of the first oxide semiconductor layer and the second oxide semiconductor layer may include or be formed of an oxide semiconductor material including indium.

The gate insulating layer 150 and a word line WL may be sequentially arranged on a sidewall of each of the plurality of channel layers 140. The gate insulating layer 150 may be conformally arranged on an upper surface and a sidewall of each of the plurality of channel layers 140.

The word line WL may be arranged on a sidewall of the gate insulating layer 150. For example, the gate insulating layer 150 may be between the word line WL and the channel layer 140. The word line WL may longitudinally extend in the second horizontal direction (X direction) within the mold opening portion 130H.

The channel layer 140 having a U-shaped vertical cross section may be arranged within one mold opening portion 130H. A pair of word lines WL may be arranged above the channel layer 140 within one mold opening portion 130H to be spaced apart from each other in the first horizontal direction (Y direction).

The word line WL may include a first word line WL1 and a second word line WL2. The first word line WL1 may be arranged on (e.g., contact) the sidewall of the gate insulating layer 150. The second word line WL2 may be arranged on (e.g., contact) a sidewall of the first word line WL1. At this time, the second word line WL2 may be formed longer (e.g., higher) in the vertical direction (Z direction) than the first word line WL1. For example, a top surface of the second word line WL2 may be positioned higher than a top surface of the first word line WL1.

The first word line WL1 and the second word line WL2 may include or be formed of the same material. For example, each of the first word line WL1 and the second word line WL2 may include or be formed of Ti, TiN, Ta, TaN, W, WN, TiSiN, WSiN, polysilicon, or a combination thereof. However, the inventive concept is not limited thereto. For example, the first word line WL1 and the second word line WL2 may include different materials in certain embodiments.

In embodiments, an auxiliary insulating pattern 155 may be arranged between the word line WL and the gate insulating layer 150. The auxiliary insulating pattern 155 may be arranged to overlap a contact layer 170 and the gate insulating layer 150 in the first horizontal direction (Y direction). The contact layer 170 may be formed of a single pattern and a single layer. The auxiliary insulating pattern 155 may extend lengthwise in the second horizontal direction (X direction). The auxiliary insulating pattern 155 may be arranged to vertically overlap an upper surface of the first word line WL1 and to horizontally overlap a portion of a sidewall of the second word line WL2.

The auxiliary insulating pattern 155 may be arranged on the first word line WL1. The auxiliary insulating pattern 155 may be arranged to overlap the first word line WL1 in the vertical direction (Z direction). A lower surface of the auxiliary insulating pattern 155 may be arranged to be in contact with the upper surface of the first word line WL1. In some embodiments, a width of the lower surface of the auxiliary insulating pattern 155 in the first horizontal direction (Y direction) may be equal to a width of the upper surface of the first word line WL1 in the first horizontal direction (Y direction). Also, a width of the auxiliary insulating pattern 155 in the first horizontal direction (Y direction) may decrease in a direction receding from the first word line WL1 in the vertical direction (Z direction), but the inventive concept is not limited thereto. For example, the area in the X-Y direction of the bottom surface of the auxiliary insulating pattern 155 is the same as the area of the top surface of the first word line WL1 in the X-Y direction in certain embodiments. For example, the auxiliary insulating pattern 155 may cover the entire top surface of the first word line WL1 and may not extend beyond the first word line WL1. For example, the entire top surface of the first word line WL1 may be the upper most surface of the first word line WL1 which is substantially parallel to a horizontal plane.

The auxiliary insulating pattern 155 may include a first side surface and a second side surface. At this time, the first side surface may be a surface in contact with the sidewall of the second word line WL2. The second side surface is a surface opposite the first side surface in the first horizontal direction (Y direction), which may be a surface in contact with an upper end portion of the sidewall of the gate insulating layer 150. At this time, the first side surface of the auxiliary insulating pattern 155 may include or may be a curved surface, but is not limited thereto.

The auxiliary insulating pattern 155 may include or be formed of silicon nitride (SiN), but is not limited thereto. For example, the auxiliary insulating pattern 155 may include or be formed of a high-k dielectric material.

In embodiments, a vertical level LV2 of the upper/top surface of the first word line WL1 may be the same as a vertical level LV1 of the upper/top surface of the channel layer 140. However, the inventive concept is not limited thereto, and the vertical level LV2 of the upper surface of the first word line WL1 may be higher or lower than the vertical level LV1 of the upper surface of the channel layer 140. In addition, a vertical level of an upper/top surface of the second word line WL2 may be higher than the vertical level LV1 of the upper/top surface of the channel layer 140. The vertical level of the upper/top surface of the second word line WL2 may be not higher than a vertical level LV3 of the upper/top surface of the gate insulating layer 150. FIGS. 3 and 4 illustrate that the vertical level of the upper/top surface of the second word line WL2 is the same as the vertical level LV3 of the upper/top surface of the gate insulating layer 150, but the inventive concept is not limited thereto, and the vertical level of the upper surface of the second word line WL2 may be lower than the vertical level LV3 of the upper surface of the gate insulating layer 150. Each of the top/upper surfaces of the first word line WL1, the second word line WL2, the channel layer 140, and the gate insulating layer 150 may be parallel or substantially parallel to a horizontal plane.

A vertical level of a lower/bottom surface of the auxiliary insulating pattern 155 may be the same as the vertical level LV2 of the upper/top surface of the first word line WL1. The vertical level of the lower/bottom surface of the auxiliary insulating pattern 155 may be at least at the vertical level LV1 of the upper/top surface of the channel layer 140. For example, the vertical level of the bottom surface of the auxiliary insulating pattern 155 may be the same as or higher than the vertical level LV1 of the top surface of the channel layer 140. In addition, a vertical level of the upper/top surface of the auxiliary insulating pattern 155 may be at least at the vertical level LV3 of the upper/top surface of the gate insulating layer 150. For example, the vertical level of the top surface of the auxiliary insulating pattern 155 may be the same as or higher than the vertical level LV3 of the top surface of the gate insulating layer 150. The bottom/lower surface of the auxiliary insulating pattern 155 may be parallel or substantially parallel to a horizontal plane.

In embodiments, as the semiconductor device 100 according to the inventive concept includes the auxiliary insulating pattern 155 between the word line WL and the gate insulating layer 150, electrical characteristics of the semiconductor device 100 may be improved. In particular, a decrease in time dependent dielectric breakdown (TDDB) reliability between the contact layer 170, the gate insulating layer 150, and the word line WL due to damage to a portion of the sidewall of the gate insulating layer 150 in a process of forming the contact layer 170 may be prevented. In addition, as the semiconductor device 100 according to the inventive concept includes the auxiliary insulating pattern 155, current leakage due to damage to the gate insulating layer 150 may be prevented. In addition, as the semiconductor device 100 according to the inventive concept includes the auxiliary insulating pattern 155, structural stability of the semiconductor device 100 may be improved.

In embodiments, the gate insulating layer 150 may include at least one selected from a high-k dielectric material having a higher dielectric constant than that of silicon oxide and a ferroelectric material. In some embodiments, the gate insulating layer 150 may include at least one material selected from hafnium oxide (HfO), hafnium silicate (HfSiO), hafnium oxide nitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO) and lead scandium tantalum oxide (PbScTaO).

An insulating liner 182 and a first insulating layer 184 may be arranged between the pair of word lines WL within each of the plurality of mold opening portions 130H. A plurality of insulating liners 182 may be arranged on each word line WL. The first insulating layer 184 may be between the plurality of insulating liners 182 and may have a pillar-shaped cross section. However, the shapes of the insulating liner 182 and the first insulating layer 184 are not limited thereto and may be designed in various ways as necessary.

The contact layer 170 may be formed on the channel layer 140. For example, the contact layer 170 may be in contact with the upper/top surface of the channel layer 140. In some embodiments, a lowermost end of the contact layer 170 may be positioned at a vertical level lower than that of the upper/top surface of the word line WL. For example, the lowermost end of the contact layer 170 may be positioned at a vertical level lower than that of the upper/top surface of the second word line WL2. The lowermost end of the contact layer 170 may be a bottom surface of the contact layer 170 and may be parallel or substantially parallel to a horizontal plane.

The contact layer 170 may electrically connect the channel layer 140 and a capacitor structure 190 to each other. The capacitor structure 190 may be a capacitor including two electrodes and a dielectric layer interposed therebetween. The contact layer 170 may include at least one of a conductive material, for example, a conductive metal nitride, a conductive metal carbonitride, a conductive metal carbide, a metal silicide, a doped semiconductor material, a conductive metal oxynitride, and/or a conductive metal oxide, and a two-dimensional (2D) material, but is not limited thereto. As used herein, components described as being “electrically connected” are configured such that an electrical signal can be transferred from one component to the other (although such electrical signal may be attenuated in strength as it transferred and may be selectively transferred).

A second insulating layer 186 may be arranged on each of both sidewalls of the contact layer 170. Although an upper/top surface of the second insulating layer 186 is illustrated to be positioned at the same level as upper/top surfaces of a plurality of contact layers 170, the inventive concept is not limited thereto. For example, the upper/top surface of the second insulating layer 186 may be positioned at a higher level than the upper surfaces of the plurality of contact layers 170.

The insulating liner 182 may include or be formed of silicon nitride, and the first insulating layer 184 may include or be formed of silicon oxide. The second insulating layer 186 may include or be formed of silicon nitride.

An etch stop film 188 may be arranged on the contact layer 170 and the second insulating layer 186. The etch stop film 188 may include an opening portion (e.g., an opening) 188H, and the upper surface of the contact layer 170 may be exposed at a bottom portion (e.g., at a bottom) of the opening portion 188H.

The capacitor structure 190 may be arranged on the etch stop film 188. The capacitor structure 190 may include a lower electrode 192, a capacitor dielectric layer 194, and an upper electrode 196. A sidewall of a bottom portion of the lower electrode 192 may be arranged within the opening portion 188H of the etch stop film 188, and the lower electrode 192 may extend in the vertical direction (Z direction). The capacitor dielectric layer 194 may be arranged on a sidewall of the lower electrode 192, and the upper electrode 196 may be arranged on the capacitor dielectric layer 194 to cover the lower electrode 192. The lower electrode 192 may contact the contact layer 170.

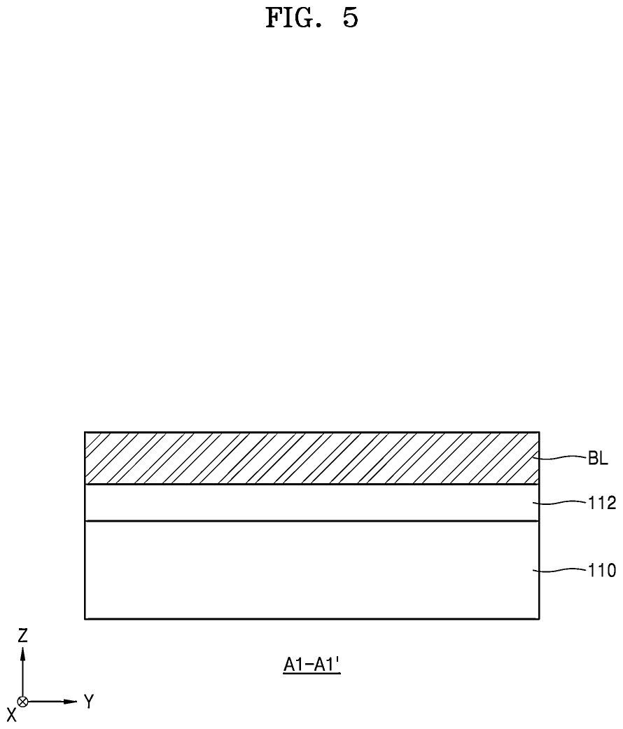

FIGS. 5 to 18 are cross-sectional views illustrating a method of manufacturing the semiconductor device 100 according to embodiments. In FIGS. 5 to 18, like reference numerals as in FIGS. 1 to 4 denote like components.

Referring to FIG. 5, the lower insulating layer 112 is formed on the substrate 110. Thereafter, the plurality of bit lines BL extending lengthwise in the first horizontal direction (Y direction) and a bit line insulating layer (not shown) filling a space between the plurality of bit lines BL may be formed on the lower insulating layer 112. In embodiments, each of the plurality of bit lines BL may include a conductive barrier layer, a conductive layer, and a conductive barrier layer, which are sequentially arranged, e.g., in a vertical direction.

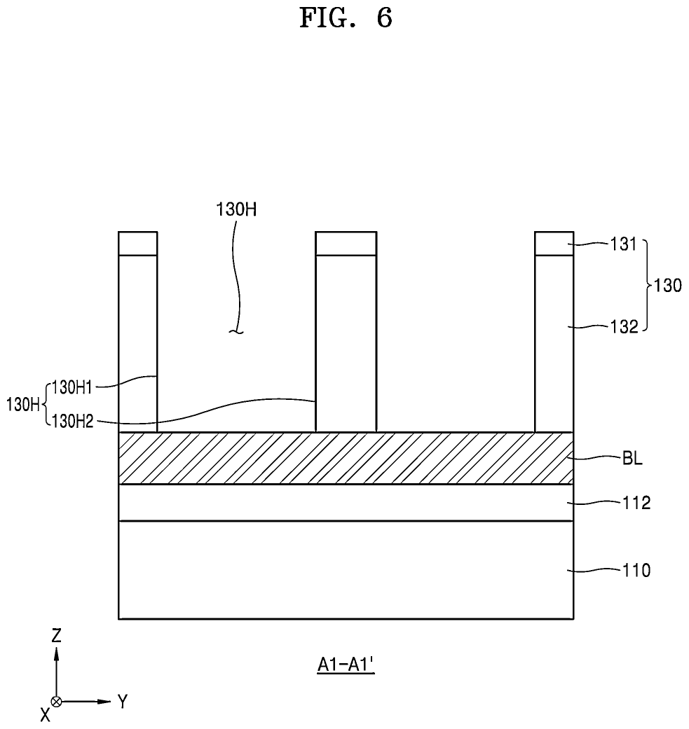

Referring to FIG. 6, the first mold layer 130 may be formed on the plurality of bit lines BL and the bit line insulating layer. In some embodiments, the first mold layer 130 may be formed in a stacked structure. The first mold layer 130 may include or be formed of at least one of silicon oxide, silicon nitride, and silicon oxynitride and may be formed to have a relatively large height in the vertical direction (Z direction).

The first mold layer 130 may include or be formed of at least one of silicon oxide, silicon nitride, and silicon oxynitride. According to an embodiment, the first mold layer 130 may be formed as a multi-layered structure. For example, the first mold layer 130 may include or be formed of the first insulating film 131 and the second insulating film 132. At this time, the first insulating film 131 may include or be formed of silicon nitride, and the second insulating film 132 may include or be formed of silicon oxide. In addition, the thickness of the second insulating film 132 in a vertical direction (Z direction) may be greater than the thickness of the first insulating film 131 in the vertical direction, but the inventive concept is not limited thereto.

The second insulating film 132 may be arranged on the bit line BL. The first insulating film 131 may be arranged on the second insulating film 132. FIG. 6 illustrates that the first mold layer 130 includes two insulating films, but the inventive concept is not limited thereto. For example, the first mold layer 130 may be formed as a single-layered structure or may include three or more layers.

A plurality of first mold layers 130 may extend lengthwise in the second horizontal direction (X direction) and may be formed to be spaced apart from each other at equal interval in the first horizontal direction (Y direction). The mold opening portion 130H extending lengthwise in the second horizontal direction (X direction) may be formed between the plurality of first mold layers 130. For example, the mold opening portion 130H a space formed between two adjacent first mold layers 130.

The mold opening portion 130H may be formed by forming a mask pattern (not shown) on the first mold layer 130 and using the mask pattern as an etch mask. The upper surface of the bit line BL may be exposed at bottom portions of the plurality of mold opening portions 130H. The plurality of mold opening portions 130H may include the first sidewall 130H1 and the second sidewall 130H2, which are opposite to each other. For example, the first sidewall 130H1 and the second sidewall 130H2 may face each other.

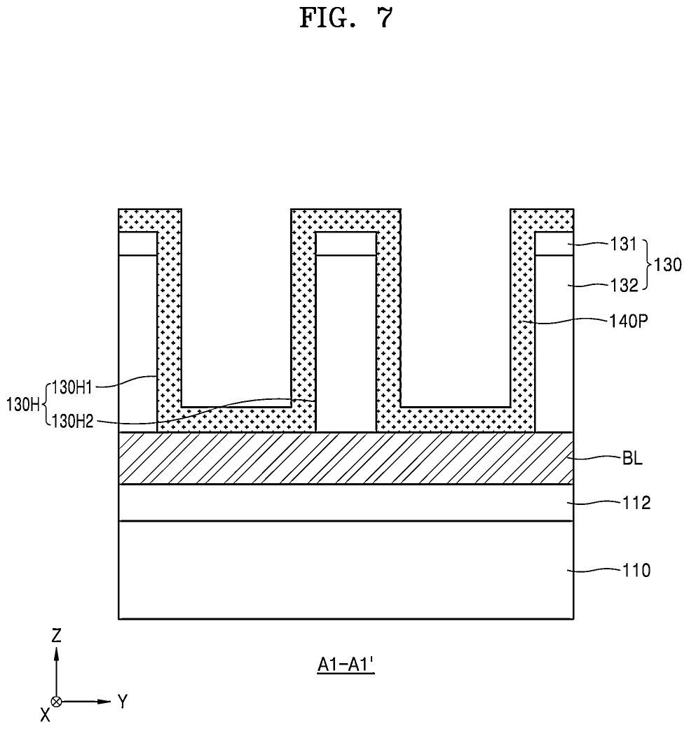

Referring to FIG. 7, a preliminary channel layer 140P may be conformally formed on the first mold layer 130 to conformally cover an inner wall of the mold opening portion 130H.

In embodiments, the preliminary channel layer 140P may be formed by using (e.g., formed of) an oxide semiconductor material. The preliminary channel layer 140P may include or be formed of an oxide semiconductor material including indium. For example, the oxide semiconductor material may include at least one of InGaZnOx (IGZO), Sn-doped IGZO, W-doped IGZO, and InZnOx (IZO).

In embodiments, the preliminary channel layer 140P may be formed by using at least one of a chemical vapor deposition (CVD) process, a low-pressure CVD process, a plasma-enhanced CVD process, a metal-organic CVD (MOCVD) process, and an atomic layer deposition process.

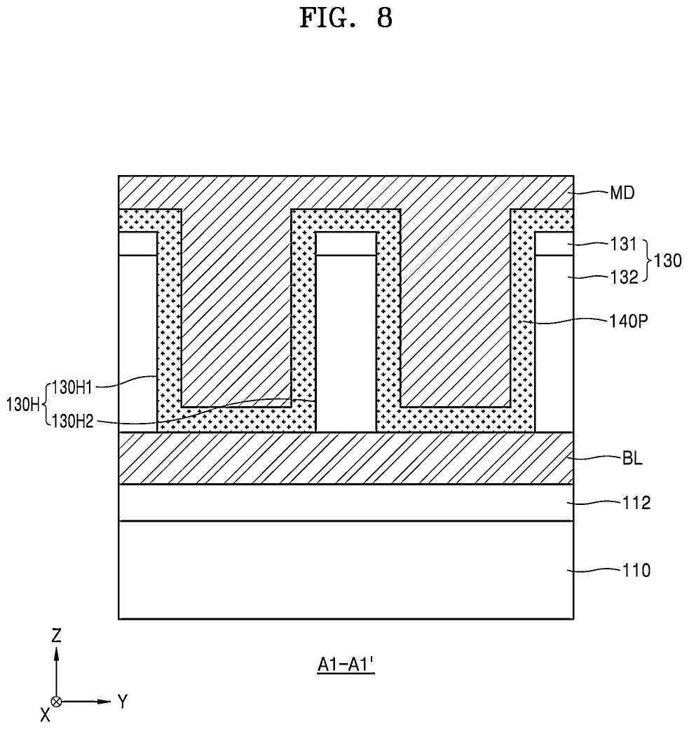

Referring to FIG. 8, a second mold layer MD covering the preliminary channel layer 140P and filling a portion of the mold opening portion 130H may be formed. A plurality of second mold layers MD may extend lengthwise in the second horizontal direction (X direction).

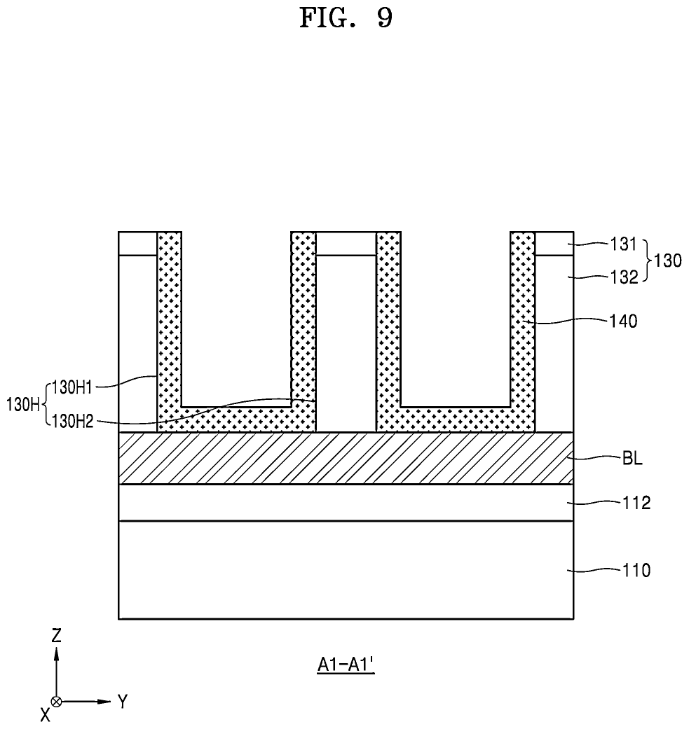

Referring to FIG. 9, the plurality of channel layers 140 may be formed by etching back the second mold layer MD. When the second mold layer MD is removed, a portion of the preliminary channel layer 140P may be removed together. The plurality of channel layers 140 may be formed by removing a portion of the preliminary channel layer 140P, the portion covering the upper surface of the first mold layer 130.

In embodiments, the channel layer 140 may remain within the mold opening portion 130H by removing the preliminary channel layer 140P. The preliminary channel layer 140P may be removed by an etch-back process or a planarization process. For example, upper portions of the preliminary channel layer 140P may be removed together with an upper portion of the second mold layer MD by a planarization process or by an etch-back process, thereby exposing upper portions of the first mold layers 130 and forming the plurality of second mold layers MD extending lengthwise in the second horizontal direction (X direction).

The channel layer 140 having a U-shaped vertical cross section may be formed within the mold opening portion 130H by the etch-back process or the planarization process. In addition, as the preliminary channel layer 140P on the upper surface of the first mold layer 130 is removed, the upper surface of the first mold layer 130 may be exposed. At this time, the upper surface of the channel layer 140 may be arranged at the same level as the upper surface of the first mold layer 130.

Each of the plurality of channel layers 140 may cover inner sidewalls and a bottom surface of the mold opening portion 130H. Each of the plurality of channel layers 140 may be formed to have a U-shaped vertical cross section. At this time, a level of the upper surface of the channel layer 140 in the vertical direction (Z direction) may be the same as a level of the upper surface of the first mold layer 130 in the vertical direction (Z direction).

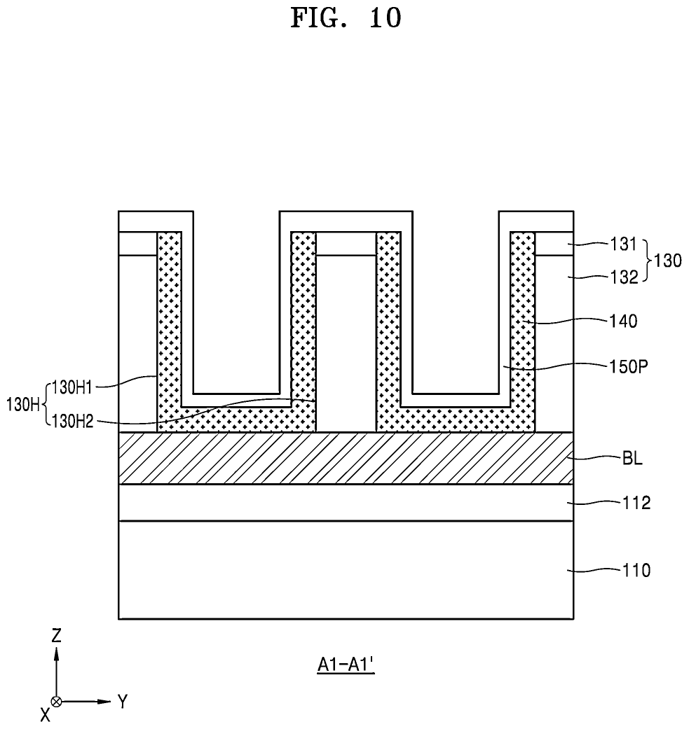

Referring to FIG. 10, a preliminary gate insulating layer 150P covering the channel layer 140 and the first mold layer 130 may be sequentially formed. The preliminary gate insulating layer 150P may conformally cover sidewalls and the upper surface of the channel layer 140. The preliminary gate insulating layer 150P may cover the upper surface of the first mold layer 130.

In embodiments, the channel layer 140 may include a first portion extending in the first horizontal direction (Y direction) and a second portion connected to each of both ends of the first portion and extending in the vertical direction (Z direction). The second portion may include a first sidewall and a second sidewall. The first sidewall of the second portion may be exposed, and the second sidewall of the second portion may be surrounded by and/or contact the first mold layer 130.

The preliminary gate insulating layer 150P may include at least one selected from a high-k dielectric material having a higher dielectric constant than that of silicon oxide and a ferroelectric material. In some embodiments, the preliminary gate insulating layer 150P may include at least one material selected from hafnium oxide (HfO), hafnium silicate (HfSiO), hafnium oxide nitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO) and lead scandium tantalum oxide (PbScTaO).

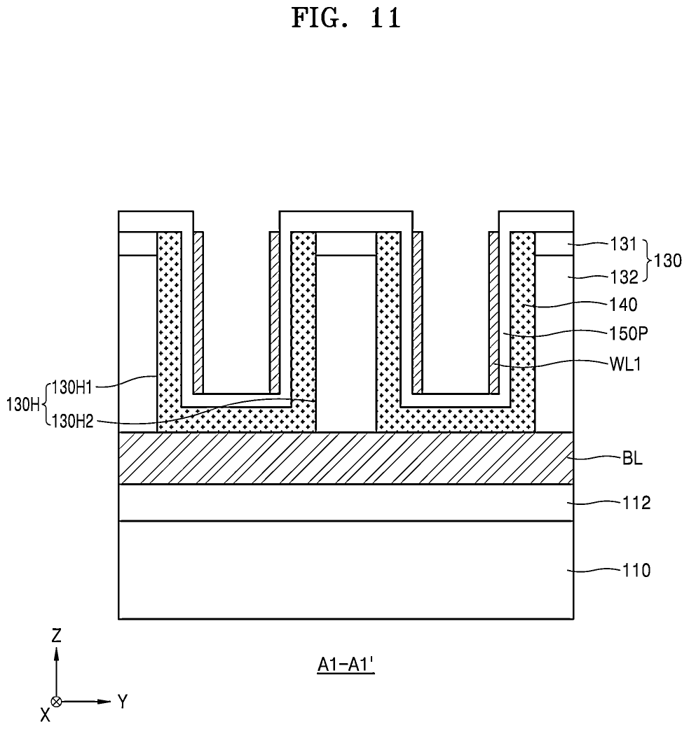

Referring to FIG. 11, the first word line WL1 covering a sidewall of the preliminary gate insulating layer 150P may be formed. After forming a preliminary gate electrode layer (not shown) conformally covering the preliminary gate insulating layer 150P, the first word line WL1 may be formed by removing a portion of the preliminary gate electrode layer by performing an etching process. In embodiments, the first word line WL1 may include or be formed of Ti, TiN, Ta, TaN, W, WN, TiSiN, WSiN, polysilicon, or a combination thereof.

In embodiments, a plurality of first word lines WL1 may be respectively arranged on the first sidewall 130H1 and the second sidewall 130H2 of the plurality of mold opening portions 130H. The first word line WL1 may be formed within the mold opening portion 130H to cover a sidewall of the channel layer 140 and extend in the vertical direction (Z direction). The first word line WL1 may be formed such that the upper surface of the channel layer 140 is exposed. The first word line WL1 may be formed to extend lengthwise in the second horizontal direction (X direction).

In some embodiments, a pair of first word lines WL1 may be formed within each of the plurality of mold opening portions 130H to face each other. The pair of first word lines WL1 may be spaced apart from each other in the first horizontal direction (Y direction) and may each extend lengthwise in the second horizontal direction (X direction).

At this time, a vertical level of the upper surface of the first word line WL1 may be substantially the same as or similar to the vertical level of the upper surface of the channel layer 140. In addition, the vertical level of the upper surface of the first word line WL1 may be substantially the same as or similar to the vertical level of the upper surface of the first mold layer 130. Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

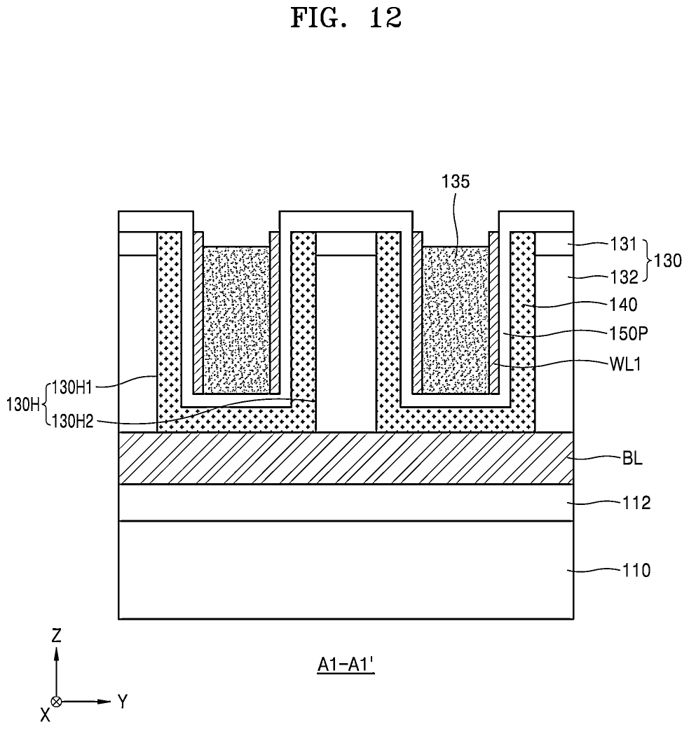

Referring to FIG. 12, a plurality of third mold layers 135 each covering a corresponding pair of first word lines WL1 and the preliminary gate insulating layer 150P and filling a portion of a corresponding mold opening portion 130H are formed. A third mold layer 135 may cover a portion of a sidewall of the first word line WL1 and an upper surface of the preliminary gate insulating layer 150P, e.g., at a bottom area of a mold opening portion 130H. The plurality of third mold layers 135 may extend lengthwise in the second horizontal direction (X direction). The third mold layer 135 may include or may be a spin-on-hardmask (SOH), but is not limited thereto.

The third mold layer 135 may be formed to fill the mold opening portion 130H and then etched back in the vertical direction (Z direction). A vertical level of an upper/top surface of the third mold layer 135 may be formed to be lower than the vertical level of the upper surface of the first word line WL1. The vertical level of the upper surface of the third mold layer 135 may be formed to be lower than the vertical level of the upper surface of the channel layer 140. The upper/top surface of the third mold layer 135 may be parallel or substantially parallel to a horizontal plane.

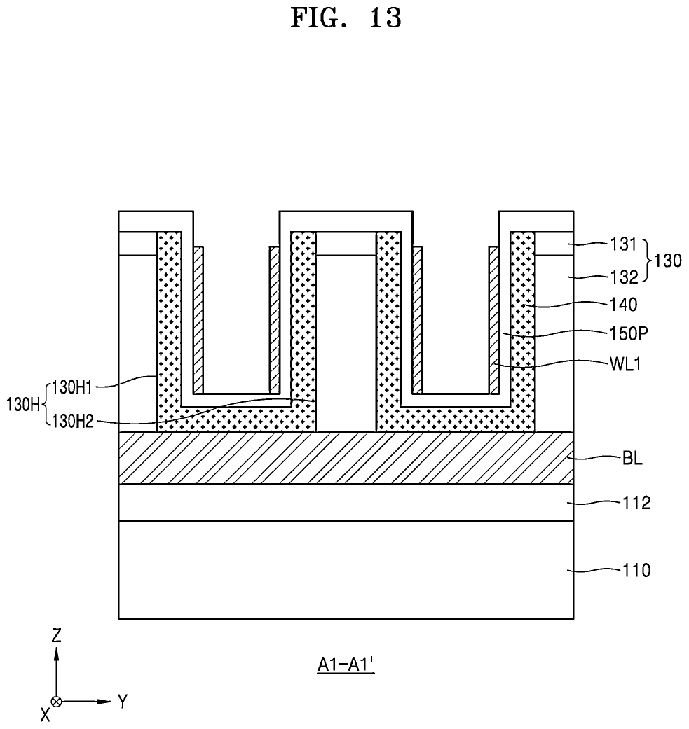

Referring to FIG. 13, a portion of an upper part/side of the first word line WL1 in the vertical direction (Z direction) may be removed by an etching process. The vertical level of the upper surface of the first word line WL1 after the removal may be substantially the same as or similar to the vertical level of the upper surface of the third mold layer 135 shown in FIG. 12. A portion of the upper part/side of the first word line WL1 may be removed by using the third mold layer 135 as an etch mask. Accordingly, the vertical level of the upper surface of the first word line WL1 may be formed to be lower than the vertical level of the upper surface of the channel layer 140.

Thereafter, the third mold layer 135 filling a portion of the mold opening portion 130H may be removed. The third mold layer 135 may be removed by an ashing process and a strip process.

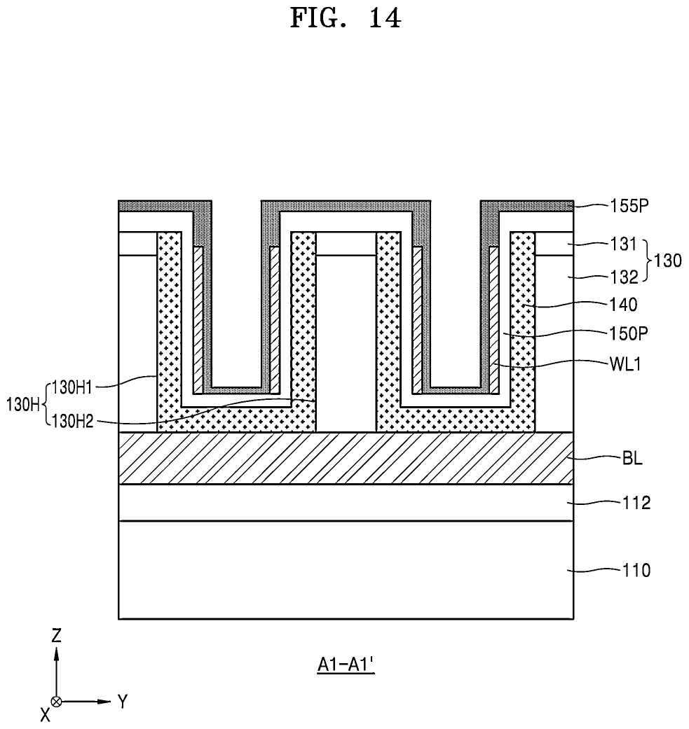

Referring to FIG. 14, a preliminary auxiliary insulating pattern 155P may be formed. The preliminary auxiliary insulating pattern 155P may be formed to cover the first word line WL1 and the preliminary gate insulating layer 150P. The preliminary auxiliary insulating pattern 155P may cover/contact a sidewall and the upper surface of the first word line WL1 and extend lengthwise in the second horizontal direction (X direction). In addition, the preliminary auxiliary insulating pattern 155P may cover/contact a sidewall and the upper surface of the preliminary gate insulating layer 150P and extend lengthwise in the second horizontal direction (X direction).

In embodiments, the preliminary auxiliary insulating pattern 155P may include or be formed of silicon nitride (SiN), but is not limited thereto. For example, the preliminary auxiliary insulating pattern 155P may include or be formed of a high-k dielectric material. For example, the high-k dielectric material forming the preliminary auxiliary insulating pattern 155P may be a different material from the high-k dielectric material forming the gate insulating layer 150.

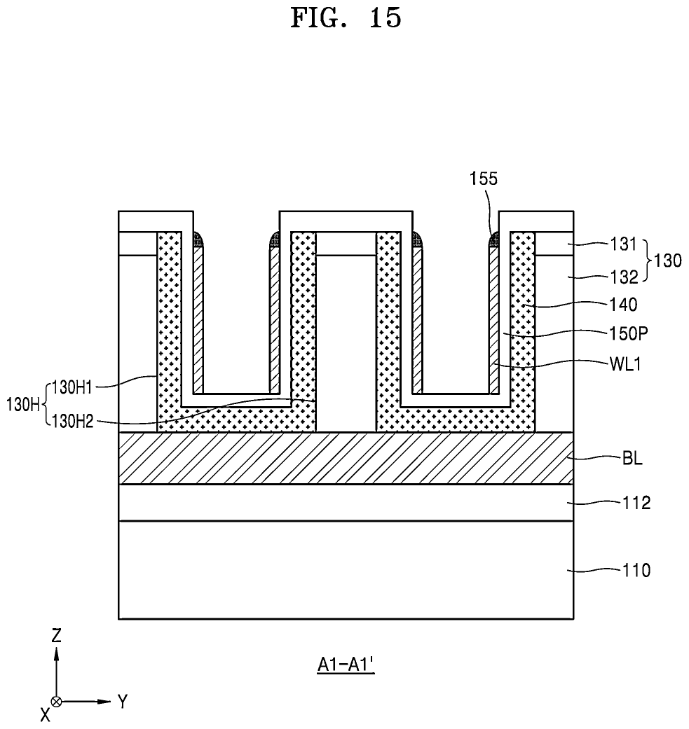

Referring to FIG. 15, the auxiliary insulating pattern 155 may be formed by removing a portion of the preliminary auxiliary insulating pattern 155P. The auxiliary insulating pattern 155 may be formed on the first word line WL1, e.g., on a top surface of the first word line WL1.

The auxiliary insulating pattern 155 may be arranged to overlap the first word line WL1 in the vertical direction (Z direction). A lower surface of the auxiliary insulating pattern 155 may be arranged to be in contact with the upper/top surface of the first word line WL1. At this time, a width of the lower surface of the auxiliary insulating pattern 155 in the first horizontal direction (Y direction) may be equal to a width of the upper surface of the first word line WL1 in the first horizontal direction (Y direction). Also, a width of the auxiliary insulating pattern 155 in the first horizontal direction (Y direction) may decrease in a direction away from the first word line WL1 in the vertical direction (Z direction), but the inventive concept is not limited thereto.

The auxiliary insulating pattern 155 may include a first side surface and a second side surface. At this time, the second side surface may be a surface in contact with an upper end portion of a sidewall of the gate insulating layer 150. The fist side surface may be a surface opposite the second side surface in the first horizontal direction (Y direction). At this time, the first side surface of the auxiliary insulating pattern 155 may include a curved surface, but is not limited thereto.

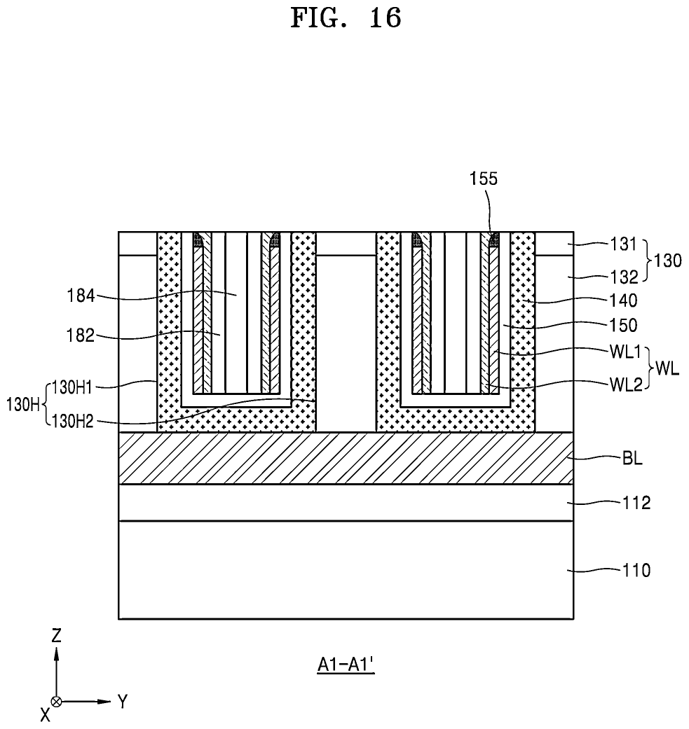

Referring to FIG. 16, the second word line WL2 covering the first word line WL1 and the auxiliary insulating pattern 155 may be formed. After forming a preliminary gate electrode layer (not shown) conformally covering the first word line WL1 and the auxiliary insulating pattern 155, the second word line WL2 may be formed by removing a portion of the preliminary gate electrode layer by performing an etching process. In embodiments, the second word line WL2 may include or be formed of Ti, TiN, Ta, TaN, W, WN, TiSiN, WSiN, polysilicon, or a combination thereof.

In embodiments, a plurality of second word lines WL2 may be respectively arranged on the first sidewalls 130H1 and the second sidewalls 130H2 of the plurality of mold opening portions 130H. The second word line WL2 may be formed within the mold opening portion 130H to cover the first word line WL1 and the auxiliary insulating pattern 155 and to extend in the vertical direction (Z direction). The second word line WL2 may be formed such that the upper surface of the preliminary gate insulating layer 150P is exposed. The second word line WL2 may be formed to extend lengthwise in the second horizontal direction (X direction).

In some embodiments, a pair of second word lines WL2 may be formed within one mold opening portion 130H to face each other. The pair of second word lines WL2 may be spaced apart from each other in the first horizontal direction (Y direction) and each of which may extend lengthwise in the second horizontal direction (X direction).

The second word line WL2 may be formed in a similar way to or the same way as the description with respect to forming the first word line WL1 given with reference to FIGS. 12 and 13. For example, after forming a fourth mold layer (not shown) covering a portion of the second word line WL2 and filling a portion of the mold opening portion 130H, a portion of an upper part/side of the second word line WL2 in the vertical direction (Z direction) may be removed by an etching process using the fourth mold layer as an etch mask.

In embodiments, the auxiliary insulating pattern 155 may be arranged between the word line WL and the gate insulating layer 150. The auxiliary insulating pattern 155 may be arranged to overlap and/or contact the upper surface of the first word line WL1 and a portion of a sidewall of the second word line WL2.

At this time, a vertical level of the upper surface of the second word line WL2 may be substantially the same as or similar to the vertical level of the upper surface of the channel layer 140. In addition, the vertical level of the upper surface of the second word line WL2 may be substantially the same as or similar to the vertical level of the upper surface of the first mold layer 130. The vertical level of the upper surface of the second word line WL2 may not be higher than the vertical level of the upper surface of the gate insulating layer 150. FIG. 16 illustrates that the vertical level of the upper surface of the second word line WL2 is the same as the vertical level of the upper surface of the gate insulating layer 150, but the inventive concept is not limited thereto, and the vertical level of the upper surface of the second word line WL2 may be lower than the vertical level of the upper surface of the gate insulating layer 150.

The gate insulating layer 150 may be formed by removing a portion of the preliminary gate insulating layer 150P covering the upper surface of the first mold layer 130 and the upper surface of the channel layer 140. The gate insulating layer 150 may be formed to have a U-shaped vertical cross section.

Thereafter, the insulating liner 182 and the first insulating layer 184 may be formed within the mold opening portion 130H. The insulating liner 182 and the first insulating layer 184 may be arranged between a pair of word lines WL adjacent to each other. The insulating liner 182 and the first insulating layer 184 may be formed through an etch-back process or a planarization process. For example, after a preliminary insulating liner layer and a preliminary first insulating layer may be formed on the first mold layer 130, the channel layer 140, the gate insulating layer 150, and the word lines WL, an etching (etch-back/blanket-etch) process or a planarization process may remove an upper part of the preliminary insulating liner layer and an upper part of the preliminary first insulating layer to form the insulating liner 182 and the first insulating layer 184. In certain embodiments, after forming the insulating liner 182 by forming a preliminary insulating liner layer on the first mold layer 130, the channel layer 140, the gate insulating layer 150, and the word lines WL and by removing an upper part of the preliminary insulating liner layer by an etching (etch-back/blanket-etch) process or a planarization process, a preliminary first insulating layer may be formed on the insulating liner 182, the first mold layer 130, the channel layer 140, the gate insulating layer 150, and the word lines WL, and then the first insulating layer 184 may be formed by removing an upper part of the preliminary first insulating layer by an etching (etch-back/blanket-etch) process or a planarization process.

Accordingly, the first cell transistor CTR1 and the second cell transistor CTR2 may be formed within the mold opening portion 130H. The first cell transistor CTR1 and the second cell transistor CTR2 may be spaced apart from each other in the first horizontal direction (Y direction) and/or the second horizontal direction (X direction) and may be arranged in a mirror symmetrical shape with respect to each other. For example, a first cell transistor CTR1 and a second cell transistor CTR2 formed in a mold opening portion 130H may have mirror symmetries with respect to each other.

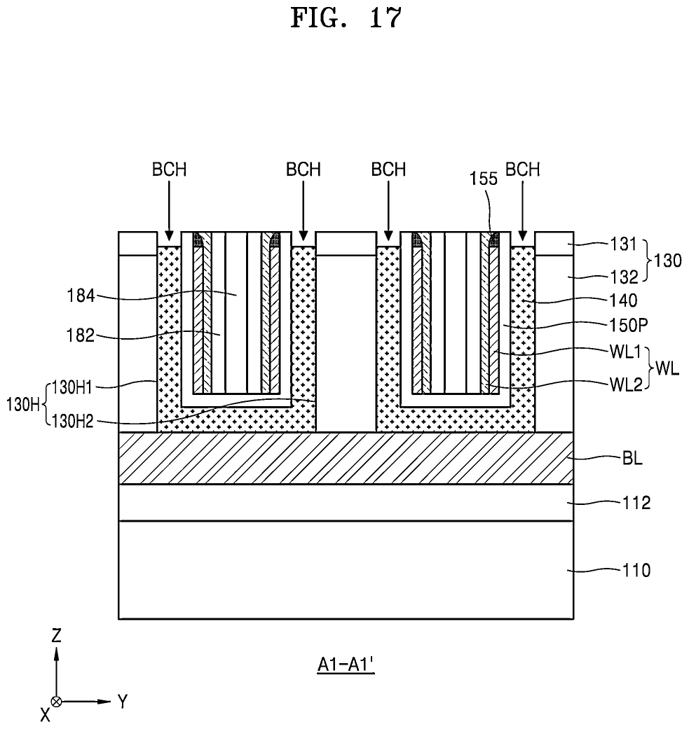

Referring to FIG. 17, a portion of an upper side of the channel layer 140 may be removed by performing a recess process. A contact hole BCH may be formed by removing a portion of the upper side of the channel layer 140. By removing a portion of the upper side of the channel layer 140, the vertical level of the upper surface of the channel layer 140 may be substantially the same as or similar to the vertical level of the upper surface of the first word line WL1. However, the inventive concept is not limited thereto, and the vertical level of the upper surface of the channel layer 140 may be formed to be lower than the vertical level of the upper surface of the first word line WL1. Also, the vertical level of the upper surface of the channel layer 140 may be formed to be lower than the vertical level of the upper surface of the second word line WL2.

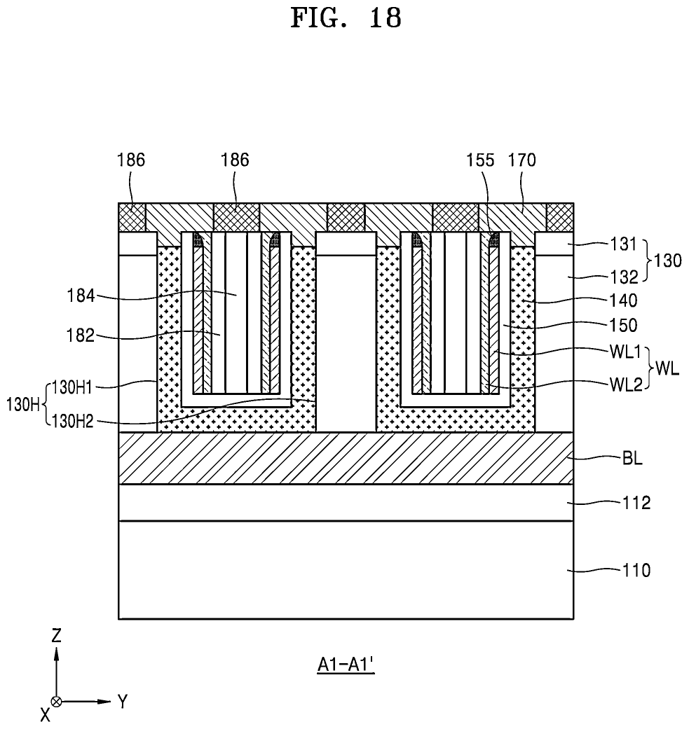

Referring to FIG. 18, the contact layer 170 and the second insulating layer 186 may be formed.

The contact layer 170 may be formed by forming a mask pattern (not shown) on a contact conductive layer (not shown) and removing a portion of the contact conductive layer by using the mask pattern, and the second insulating layer 186 may be formed in an area in which the contact conductive layer is removed. In embodiments, the contact layer 170 may include or be formed of Ti, TiN, Ta, TaN, W, WN, TiSiN, WSiN, polysilicon, or a combination thereof.

In embodiments, the auxiliary insulating pattern 155 may be arranged to overlap the contact layer 170 and the gate insulating layer 150 in the first horizontal direction (Y direction). As the semiconductor device 100 according to the inventive concept includes the auxiliary insulating pattern 155 overlapping the contact layer 170 and the gate insulating layer 150 in the first horizontal direction (Y direction), current leakage due to damage to the gate insulating layer 150 may be prevented. In addition, as the semiconductor device 100 according to the inventive concept includes the auxiliary insulating pattern 155, structural stability of the semiconductor device 100 may be improved.

In embodiments, the second insulating layer 186 may be formed by using (e.g., formed of) silicon nitride. In addition, in the semiconductor device 100 formed by the above described method, a sidewall of the contact layer 170 may be surrounded by the second insulating layer 186, and a bottom surface of the contact layer 170 may cover/contact a portion of the first mold layer 130, the channel layer 140, the gate insulating layer 150, and/or the insulating liner 182.

Referring to FIG. 3 again, the etch stop film 188 may be formed on the contact layer 170 and the second insulating layer 186. The etch stop film 188 may include the opening portion 188H, and the upper surface of the contact layer 170 may be exposed at the bottom portion of the opening portion 188H. Thereafter, the lower electrode 192, the capacitor dielectric layer 194, and the upper electrode 196 may be sequentially formed on the etch stop film 188.

A plurality of lower electrodes 192 may be formed to extend in the vertical direction (Z direction) from the upper surface of the contact layer 170, wherein the upper surface of the contact layer 170 is exposed at a bottom of the opening portion 188H of the etch stop film 188. Thereafter, the semiconductor device 100 including a plurality of capacitor structures 190 may be formed by sequentially forming the capacitor dielectric layer 194 and the upper electrode 196 on the plurality of lower electrodes 192.

At this time, the lower electrode 192 is shown as being formed to have a pillar shape extending in the vertical direction (Z direction) from the upper surface of the contact layer 170, but the inventive concept is not limited thereto, and the lower electrode 192 may be formed to have a cylinder shape extending in the vertical direction (Z direction) from the upper surface of the contact layer 170. The capacitor dielectric layer 194 may be formed to conformally extend along a profile of side surfaces and upper surfaces of the plurality of lower electrodes 192 and an upper surface of the etch stop film 188. The upper electrode 196 may be formed to cover the capacitor dielectric layer 194.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate;
a bit line extending on the substrate in a first horizontal direction;
a first mold layer on the bit line, wherein the first mold layer comprises a mold opening portion exposing a portion of an upper surface of the bit line and extends in a second horizontal direction crossing the first horizontal direction;
a channel layer arranged on the bit line;
a word line arranged within the mold opening portion and extending in the second horizontal direction;
a gate insulating layer arranged between the word line and the channel layer;
a capacitor structure on the first mold layer;
a contact layer between the channel layer and the capacitor structure; and
an auxiliary insulating pattern arranged to overlap the contact layer and the gate insulating layer in the first horizontal direction and extending on the word line in the second horizontal direction.

2. The semiconductor device of claim 1, wherein the word line comprises:
a first word line arranged on a sidewall of the gate insulating layer; and
a second word line arranged on the first word line and the auxiliary insulating pattern.

3. The semiconductor device of claim 2, wherein a vertical level of an upper surface of the first word line is the same as a vertical level of an upper surface of the channel layer, and
a vertical level of an upper surface of the second word line is higher than the vertical level of the upper surface of the channel layer.

4. The semiconductor device of claim 2, wherein the first word line and the second word line comprise the same material.

5. The semiconductor device of claim 2, wherein the auxiliary insulating pattern is arranged to overlap the first word line in a vertical direction.

6. The semiconductor device of claim 5, wherein a vertical level of a lower surface of the auxiliary insulating pattern is at least at a vertical level of an upper surface of the channel layer.

7. The semiconductor device of claim 5, wherein a vertical level of an upper surface of the auxiliary insulating pattern is not higher than a vertical level of an upper surface of the gate insulating layer.

8. The semiconductor device of claim 2, wherein a width of a lower surface of the auxiliary insulating pattern in the first horizontal direction is equal to a width of an upper surface of the first word line in the first horizontal direction.

9. The semiconductor device of claim 8, wherein a width of the auxiliary insulating pattern in the first horizontal direction decreases in a vertical direction receding from the first word line.

10. The semiconductor device of claim 2, wherein the auxiliary insulating pattern comprises a first side surface in contact with a sidewall of the second word line, wherein the first side surface comprises a curved surface.

11. A semiconductor device comprising:
a substrate;
a bit line extending on the substrate in a first horizontal direction;
a first mold layer on the bit line, wherein the first mold layer comprises a mold opening portion exposing a portion of an upper surface of the bit line and extends in a second horizontal direction crossing the first horizontal direction;
a channel layer arranged on the bit line;
a word line arranged within the mold opening portion and extending in the second horizontal direction;
a gate insulating layer arranged between the word line and the channel layer;
a capacitor structure on the first mold layer;
a contact layer between the channel layer and the capacitor structure; and
an auxiliary insulating pattern arranged between the word line and the gate insulating layer to extend in the second horizontal direction and overlap the contact layer and the gate insulating layer in the first horizontal direction,
wherein the word line comprises:
a first word line arranged on a sidewall of the gate insulating layer; and
a second word line arranged on the first word line and being longer in a vertical direction than the first word line.

12. The semiconductor device of claim 11, wherein the auxiliary insulating pattern is arranged to contact an upper surface of the first word line and a portion of a sidewall of the second word line.

13. The semiconductor device of claim 11, wherein the auxiliary insulating pattern comprises silicon nitride or a high-k dielectric material.

14. The semiconductor device of claim 11, wherein the first word line and the second word line comprise the same material.

15. The semiconductor device of claim 11, wherein a vertical level of an upper surface of the first word line is equal to a vertical level of an upper surface of the channel layer.

16. The semiconductor device of claim 15, wherein a vertical level of an upper surface of the second word line is not higher than a vertical level of an upper surface of the gate insulating layer and is at least at the vertical level of the upper surface of the channel layer.

17. The semiconductor device of claim 11, wherein the channel layer comprises one or more oxide semiconductor material layers.

18. A semiconductor device comprising:
a substrate;
a bit line extending on the substrate in a first horizontal direction;
a first mold layer on the bit line, wherein the first mold layer comprises a mold opening portion exposing a portion of an upper surface of the bit line and extends in a second horizontal direction crossing the first horizontal direction;
a channel layer arranged on the bit line;
a word line, which is arranged within the mold opening portion and extends in the second horizontal direction, wherein the word line comprises a first word line arranged on the channel layer and a second word line arranged on the first word line and being longer in a vertical direction than the first word line;
a gate insulating layer arranged between the word line and the channel layer;
a capacitor structure on the first mold layer;
a contact layer between the channel layer and the capacitor structure; and
an auxiliary insulating pattern between the word line and the gate insulating layer to extend in the second horizontal direction,
wherein the auxiliary insulating pattern is arranged to overlap the contact layer and the gate insulating layer in the first horizontal direction and contact an upper surface of the first word line and a portion of a sidewall of the second word line.

19. The semiconductor device of claim 18, wherein a width of a lower surface of the auxiliary insulating pattern in the first horizontal direction is equal to a width of an upper surface of the first word line in the first horizontal direction.

20. The semiconductor device of claim 18, wherein a vertical level of a lower surface of the auxiliary insulating pattern is at least at a vertical level of an upper surface of the channel layer, and
a vertical level of an upper surface of the auxiliary insulating pattern is not higher than a vertical level of an upper surface of the gate insulating layer.
